(19) United States
(12) Patent Application Publication
(10) Pub. No.: US 2006/0194427 A1
(43) Pub. Date: Aug. 31, 2006

(54) Interconnecting process and method for fabricating complex dielectric barrier layer

(76) Inventors: Yi-Ching Wu, Yong-an Township (TW); Chris Chen, Shengang Township (TW); Chih-Hsiang Shiau, Hsinchu City (TW); Nuno Chen, Jhushan Township (TW); Leonard Chen, Daliao Township (TW)

Correspondence Address: J C PATENTS, INC., 4 VENTURE, SUITE 250, IRVINE, CA, 92618, US

(21) Appl. No.: 11/066,995

(22) Filed: Feb. 25, 2005

(51) Int. Cl. H01L 21/4763

(52) U.S. Cl. 438/624; 438/761

(57) ABSTRACT

An interconnecting process is described. First, a dielectric layer with a plurality of openings is provided. Then, a metallic layer is formed to fill up the openings. A first dielectric barrier layer is formed to cover the dielectric layer and the metallic layer. Thereafter, a second dielectric barrier layer is formed over the first dielectric barrier layer. The second dielectric barrier layer is used to repair the first dielectric barrier layer and improve the reliability and yield of the process.

### BACKGROUND OF THE INVENTION

1. Field of the Invention

The present invention relates to a semiconductor fabrication process. More particularly, the present invention relates to an interconnecting process and a method of fabricating a complex dielectric barrier layer.

2. Description of the Related Art

With the rapid progress in the integrated circuit production industry, semiconductor devices are miniaturized. With an increase in the overall level of integration, the surface of a chip can no longer provide an area large enough for fabricating metallic interconnects. To meet the demands for an increase in interconnects after the miniaturization of devices, a design having two or more metallic layers is used. In particular, a functionally complicated electronic product such as a microprocessor often requires four to five metallic layers for connecting up all the devices.

Because copper has a rather high electromigration resistance and a relatively low resistant for reducing time delay in signal transmission, copper has gradually replaced aluminum as the preferred material for forming interconnecting structures.

In a conventional interconnecting process, a dielectric layer is formed over a substrate having a device thereon. The dielectric layer is a silicon oxide layer, for example. Thereafter, an anisotropic etching process is performed to form an opening in the dielectric layer. The bottom of the opening exposes a portion of the device or a portion of the dielectric layer. Then, a copper layer is formed over the substrate to fill up the opening. After that, a chemical-mechanical polishing process is performed to remove a portion of the metallic layer until the dielectric layer is exposed. To prevent interaction between the copper layer and the dielectric layer due to a direct contact of the two, a tantalum material layer or a tantalum nitride material layer is formed on the surface of the opening before forming the copper layer.

However, using copper as the material for forming the interconnect structures has several problems. For example, copper is easily oxidized at a relatively low temperature to form copper oxide. If the copper oxide is not removed in time, then electromigration may occur in the interconnecting structures and ultimately lead to a drop in overall reliability. To increase the reliability, a surface treatment of the copper layer is carried out to remove any oxide material from the copper surface. Hydrogen-containing plasma is normally used in the aforementioned surface treatment to reduce or clear away most of the metallic oxide material.

Aside from reducing or clearing metallic oxide material, the aforementioned surface treatment may also remove a portion of the dielectric layer leading to some surface defects in the dielectric layer. Defects in the dielectric layer are particularly numerous close to the top portion of the opening.

In addition, copper is a substance that can easily diffuse into silicon oxide or other dielectric materials used for producing microcircuit systems. To deal with the defects of using copper, a dielectric barrier layer is formed between the copper layer and its neighboring layer to prevent the diffusion of copper atoms and preserve the copper surface. However, the aforementioned damages to the surface of the dielectric layer can easily lead to the formation of seams in the subsequently formed dielectric barrier layer. The seams may severely affect the reliability of the fabrication process.

Furthermore, for a dielectric barrier layer such as a silicon nitride layer formed in a high-density plasma chemical vapor deposition (HDP-CVD) process, pinholes can easily form in the dielectric barrier layer. These pinholes or seams will become the pathway for leakage. For example, in a subsequent process that uses an acid solution or gas to serve as an etchant or etching gas in an etching process, the acid solution or gas can erode the copper surface via the pinholes or seams. Meanwhile, the copper atoms can also diffuse through these pinholes into surrounding territories. Ultimately, reliability of the device and yield of the fabrication process will be severely compromised.

### SUMMARY OF THE INVENTION

Accordingly, at least one objective of the present invention is to provide an interconnecting process and a method of fabricating a complex dielectric barrier layer that can prevent defects in the dielectric barrier layer from affecting the reliability of the interconnection.

At least a second objective of the present invention is to provide an interconnecting process and a method of fabricating a complex dielectric barrier layer that can prevent the out-diffusion of copper atoms into surrounding regions and increase the reliability and yield of the fabrication process.

To achieve these and other advantages and in accordance with the purpose of the invention, as embodied and broadly described herein, the invention provides an interconnecting process. First, a dielectric layer having a plurality of openings is provided. Then, a metallic layer is formed to fill up the openings. A first dielectric barrier layer is formed to cover the dielectric layer and the metallic layer. Thereafter, a second dielectric barrier layer is formed over the first dielectric barrier layer to repair the first dielectric barrier layer.

The present invention also provides a method of fabricating a complex dielectric barrier layer suitable for forming over a substrate having a dielectric layer thereon and the dielectric layer has a plurality of metallic interconnects therein. The method includes forming a first dielectric barrier layer over the dielectric layer to cover the metallic interconnects and the dielectric layer. Thereafter, a second dielectric barrier layer is formed over the first dielectric barrier layer to repair the first dielectric layer. The first dielectric barrier layer and the second dielectric barrier together form a complex dielectric barrier layer.

According to one preferred embodiment of the present invention, the method of forming a metallic layer to fill up the openings further comprises: forming a metallic material layer on the dielectric layer, removing portion of metallic material layer to expose the surface of dielectric layer, and then performing a metallic surface treatment process. Wherein the metallic surface treatment process comprises a plasma treatment process.

According to one preferred embodiment of the present invention, the first dielectric barrier layer and the second dielectric barrier layer has a total thickness smaller than 1000 Å.

According to one preferred embodiment of the present invention, the material of the first dielectric barrier layer and the second dielectric barrier layer are the same and the method of forming the first dielectric barrier layer and the second dielectric barrier layer are different, wherein the material of the first dielectric barrier layer and the second dielectric barrier layer include silicon nitride, silicon carbide or silicon-nitrogen carbide. The first dielectric barrier layer is formed in a high-density plasma chemical vapor deposition (HDP-CVD) process and the second dielectric barrier layer is formed in a plasma-enhanced chemical vapor deposition (PECVD) process.

According to one preferred embodiment of the present invention, the material of the first dielectric barrier layer and the second dielectric barrier layer are different and the method of forming the first dielectric barrier layer and the second dielectric barrier layer are the same, wherein the material of the first dielectric barrier layer and the second dielectric barrier layer include silicon nitride, silicon carbide or silicon-nitrogen carbide. The method of forming the first dielectric barrier layer and the second dielectric barrier layer includes a high-density plasma chemical vapor deposition (HDP-CVD) process or a plasma-enhanced chemical vapor deposition (PECVD) process.

According to one preferred embodiment of the present invention, the material of metallic layer comprises copper.

In the present invention, after forming the metallic interconnects, a first dielectric barrier layer is formed. Thereafter, a second dielectric barrier layer is formed over the first dielectric barrier layer. The second dielectric barrier layer serves as a repairing material layer to repair the first dielectric barrier layer so that processing reliability problems due to defects in the first dielectric material layer is improved. More definitely, the present invention can repair defects such as seams or pinholes formed in the first dielectric barrier layer and hence prevent any acid solution or gases used in a subsequent processing operation from flowing into the metallic layer to cause surface erosion. Furthermore, once the first dielectric barrier layer is repaired, copper in the metallic layer is also prevented from diffusing into surrounding layers through the defects in the first dielectric barrier layer. Ultimately, reliability and yield of the processing is improved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1G are schematic cross-sectional views showing the interconnecting process for fabricating a complex dielectric barrier layer.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

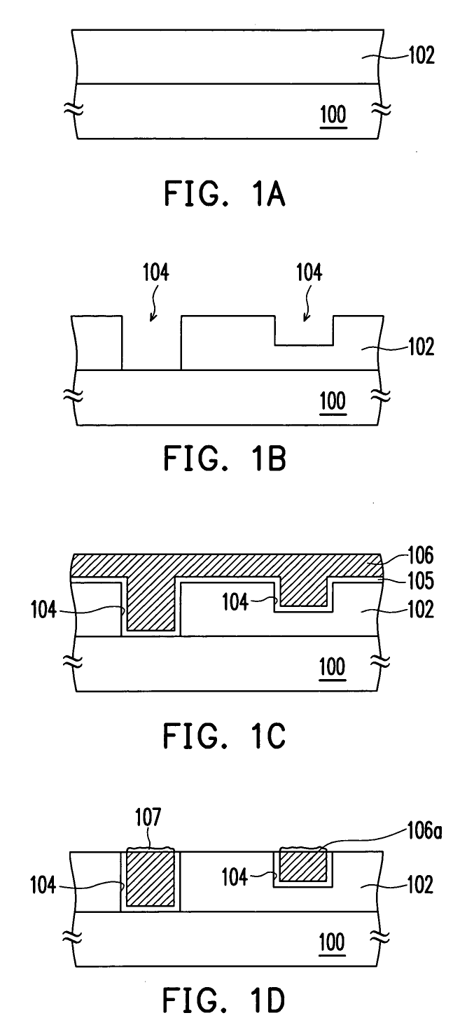

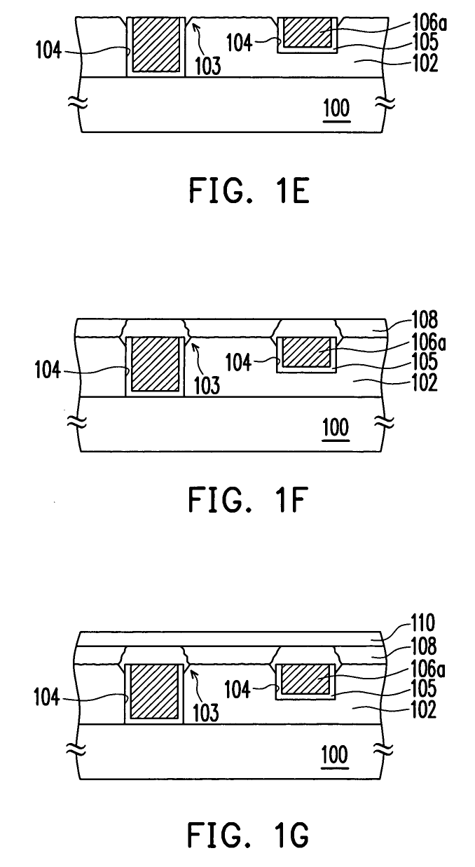

FIGS. 1A through 1G are schematic cross-sectional views showing the interconnecting process for fabricating a complex dielectric barrier layer. As shown in FIG. 1A, a substrate with a device (not shown) formed therein is provided. A dielectric layer 102 is formed over the substrate 100. The dielectric layer 102 is a silicon oxide layer formed, for example, by performing a chemical vapor deposition (CVD) process. The dielectric layer 102 can be a single layer or a multi-layered dielectric material layer and can be adjusted according to the need of the circuit design.

As shown in FIG. 1B, a plurality of openings 104 are formed in the dielectric layer 102. These openings 104 can be subsequently filled with a conductive material to serve as interconnecting lines. The method of forming the openings 104 includes, for example, performing a photolithographic process and an etching process in sequence. In addition, the aforementioned openings 104 can be a damascene opening, a contact opening, a via opening or a trench.

As shown in FIG. 1C, a metallic material layer 106 is formed over the dielectric layer 102 and filling the openings 104. Furthermore, before forming the metallic material layer 106, a material layer 105 can also be formed over the surface of the openings 104 and the dielectric layer 102 to prevent any mutual interaction due to a direct contact between the subsequently formed metallic material layer 106 and the dielectric layer 102. The material of metallic material layer 106 is copper and the material of material layer 105 is tantalum (Ta) or preferably tantalum nitride (TaN), for example.

As shown in FIG. 1D, a chemical-mechanical polishing process is carried out to remove a portion of the metallic material layer 106 until the material layer 105 is exposed. Thereafter, a portion of the material layer 105 is removed until the surface of the dielectric layer 102 is exposed so that an interconnect is formed within the dielectric layer 102.

However, similar to the conventional process, the surface of the metallic layer 160a is easily oxidized into a metallic oxide 107 (as shown in FIG. 1D) at a low temperature or an oxygen-containing atmosphere. The metallic oxide is copper oxide, for example.

As shown in FIG. 1E, a surface treatment of the metallic layer 106a is carried out to remove the metallic oxide 107. The metallic surface treatment process includes performing a plasma treatment process, such as applying a hydrogen-containing plasma to reduce and clear away the metallic oxide material. However, aside from removing the metallic oxide material 107, the surface treatment may cause some damages to the surface of the dielectric layer 103. For example, a portion of the surface material on the dielectric layer 102 may be removed. The damages are especially serious in the regions of the dielectric layer 102 close to the top section 103 of the opening.

As shown in FIG. 1F, a dielectric barrier layer 108 is formed over the substrate 100 to cover the dielectric layer 102 and the metallic layer 106a for preventing the diffusion of metallic atoms from the metallic layer 106a. However, due to the damages on the surface of the dielectric layer 102, the surface of the dielectric layer 102 is roughened and hence seams or pinholes are easily formed in the dielectric barrier layer 108.

As shown in FIG. 1G, another dielectric barrier layer 110 is formed over the dielectric barrier layer 108 to repair the defects in the underlying dielectric barrier layer 108. In other words, the dielectric barrier layer 110 can serve as a repairing material layer for repairing the seams or pinholes created in the dielectric barrier layer 108. Aside from preventing the diffusion of copper atoms to surrounding layers, the dielectric barrier layer 110 also prevents any acidic solution or reactive gases from corroding the surface of the metallic layer by flowing through the seams or the pinholes in another process. The aforementioned dielectric barrier layer 108 and the dielectric barrier layer 110 together form a complex dielectric barrier layer.

In the present invention, the complex dielectric barrier layer has a thickness smaller than 1000 Å, for example. In other words, the combined thickness of the dielectric barrier layer 108 and the dielectric barrier layer 110 is smaller than 1000 Å. In addition, the process is also not limited to combining two dielectric barrier layers together to form a complex dielectric barrier layer for improving the conventional problems. According to the requirements, a multi-layered complex dielectric barrier layer may also be formed to improve the reliability of the process.

In one embodiment, the material of the dielectric barrier layer 108 and the dielectric barrier layer 110 are the same and the method of forming the dielectric barrier layer 108 and the dielectric barrier layer 110 are different. The material forming the dielectric barrier layer 108 and 110 comprises silicon nitride, silicon carbide or silicon-nitrogen carbide, for example. The dielectric barrier layer 108 and the dielectric barrier layer 110 are performing by a high-density plasma chemical vapor deposition (HDP-CVD) and a plasma-enhanced chemical vapor deposition (PECVD) process individually, for example. In addition, the dielectric barrier layer 110 can be fabricated using carbon silicate.

In another embodiment of the present invention, the method of forming the dielectric barrier layer 108 and the dielectric barrier layer 110 are the same and the material of the dielectric barrier layer 108 and the dielectric barrier layer 110 are different. Similarly, the dielectric barrier layer 110 serves as a repairing material layer for repairing the underlying dielectric barrier layer 108 and improving the reliability of the process. More definitely, the present invention utilizes a high-density plasma chemical vapor deposition (HDP-CVD) process to form the dielectric barrier layer 108 and the dielectric barrier layer 110 using different materials. The dielectric barrier layer 108 is fabricated using silicon nitride, silicon carbide, silicon-nitrogen carbide and the dielectric barrier layer 110 is fabricated using silicon nitride, silicon carbide, silicon-nitrogen carbide or carbon silicate. Additionally, the present invention also permits using a plasma-enhanced chemical vapor deposition (PECVD) process to form the dielectric barrier layer 108 and the dielectric barrier layer 110 from different materials. The dielectric barrier layer 108 is fabricated using silicon nitride, silicon carbide, silicon-nitrogen carbide and the dielectric barrier layer 110 is fabricated using silicon nitride, silicon carbide, silicon-nitrogen carbide or carbon silicate.

In summary, after completing the fabrication of metallic interconnects in the present invention, a dielectric barrier layer is formed on the surface. Thereafter, another dielectric barrier layer serving as a repairing material layer is formed over the first dielectric barrier layer to repair the defects (as shown in FIG. 1F) such as seams or pinholes in the underlying dielectric barrier layer. Therefore, aside from preventing atomic copper from diffusing to surrounding layers through the defects in the lower dielectric barrier layer, the repairing material layer also stops any acidic solution or reactive gases from reaching the surface of the metallic layer and corroding its surface. Ultimately, the reliability and yield of the fabrication process is improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An interconnecting process, comprising the steps of:
providing a dielectric layer having a plurality of openings therein;
forming a metallic layer over the dielectric layer and filling the openings;
forming a first dielectric barrier layer to cover the dielectric layer and the metallic layer; and
forming a second dielectric barrier layer over the first dielectric barrier layer to repair the first dielectric barrier layer.

2. The interconnecting process of claim 1, wherein the method of forming a metallic layer over the dielectric layer and filling the openings comprises:
forming a metallic material layer on the dielectric layer;
removing portion of metallic material layer to expose the surface of dielectric layer; and
performing a metallic surface treatment process.

3. The interconnecting process of claim 1, wherein the metallic surface treatment process comprises a plasma treatment process.

4. The interconnecting process of claim 1, wherein the first dielectric barrier layer and the second dielectric barrier layer has a combined thickness smaller than 1000 Å.

5. The interconnecting process of claim 1, wherein the material of the first dielectric barrier layer and the second dielectric barrier layer are the same and the method of forming the first dielectric barrier layer and the second dielectric barrier layer are different.

6. The interconnecting process of claim 5, wherein the material of the first dielectric barrier layer and the second dielectric barrier layer comprises silicon nitride, silicon carbide or silicon-nitrogen carbide.

7. The interconnecting process of claim 5, wherein the method of forming the first dielectric barrier layer comprises performing a high-density plasma chemical vapor deposition (HDP-CVD) process, and the method of forming the second dielectric barrier layer comprises performing a plasma-enhanced chemical vapor deposition (PECVD) process.

8. The interconnecting process of claim 1, wherein the material of the first dielectric barrier layer and the second dielectric barrier layer are different and the method of forming the first dielectric barrier layer and the second dielectric barrier layer are the same.

9. The interconnecting process of claim 8, wherein the material of the first dielectric barrier layer and the second dielectric barrier layer comprises silicon nitride, silicon carbide or silicon-nitrogen carbide.

10. The interconnecting process of claim 8, wherein the method of forming the first dielectric barrier layer and the second dielectric barrier layer comprises performing a high-density plasma chemical vapor deposition (HDP-CVD) process or a plasma-enhanced chemical vapor deposition (PECVD) process.

11. The interconnecting process of claim 1, wherein the material of the metallic layer comprises copper.

12. A method of fabricating a complex dielectric barrier layer over a substrate with a dielectric layer thereon and a plurality of metallic interconnects in the dielectric layer, the method comprising the steps of:
forming a first dielectric barrier layer over the dielectric layer to cover the metallic interconnects and the dielectric layer; and
forming a second dielectric barrier layer over the first dielectric barrier layer to repair the first dielectric barrier layer, wherein the first dielectric barrier layer and the second dielectric barrier layer together form a complex dielectric barrier layer.

13. The method of claim 12, wherein before forming the first dielectric barrier layer, further comprises performing a metallic surface treatment of the metallic damascene structures.

14. The method of claim 13, wherein the metallic surface treatment process comprises a plasma treatment process.

15. The method of claim 12, wherein the first dielectric barrier layer and the second dielectric barrier layer has a combined thickness smaller than 1000 Å.

16. The method of claim 12, wherein the material of the first dielectric barrier layer and the second dielectric barrier layer are the same and the method of forming the first dielectric barrier layer and the second dielectric barrier layer are different.

17. The method of claim 16, wherein the material of the first dielectric barrier layer and the second dielectric barrier layer comprises silicon nitride, silicon carbide or silicon-nitrogen carbide.

18. The method of claim 16, wherein the method of forming the first dielectric barrier layer comprises performing a high-density plasma chemical vapor deposition (HDP-CVD) process, and the method of forming the second dielectric barrier layer comprises performing a plasma-enhanced chemical vapor deposition (PECVD) process.

19. The method of claim 12, wherein the material of the first dielectric barrier layer and the second dielectric barrier layer are different and the method of forming the first dielectric barrier layer and the second dielectric barrier layer are the same.

20. The method of claim 19, wherein the material of the first dielectric barrier layer and the second dielectric barrier layer comprises silicon nitride, silicon carbide or silicon-nitrogen carbide.

21. The method of claim 19, wherein the method of forming the first dielectric barrier layer and the second dielectric barrier layer comprises performing a high-density plasma chemical vapor deposition (HDP-CVD) process or a plasma-enhanced chemical vapor deposition (PECVD) process.
